(19) United States
(12) Patent Application Publication
(10) Pub. No.: US 2024/0231623 A9
(43) Pub. Date: Jul. 11, 2024

(54) IN-MEMORY COMPUTING (IMC) MEMORY DEVICE AND IMC METHOD THEREOF

(71) Applicant: MACRONIX INTERNATIONAL CO., LTD., Hsinchu (TW)

(72) Inventors: Wei-Chih CHIEN, New Taipei City (TW); Cheng-Lin SUNG, Hsinchu County (TW); Hsiang-Lan LUNG, Kaohsiung City (TW)

(21) Appl. No.: 18/049,303

(22) Filed: Oct. 25, 2022

(51) Int. Cl. G06F 3/06

(52) U.S. Cl. CPC G06F 3/061; G06F 3/0659; G06F 3/0673

(57) ABSTRACT

The disclosure provides an in-memory computing (IMC) memory device and an IMC method thereof. The IMC memory device includes; a memory array including a plurality of computing units, each of the computing units including a plurality of parallel-coupling computing cells, the parallel-coupling computing cells of the same computing unit receiving a same input voltage; wherein a plurality of input data is converted into a plurality input voltages; after receiving the input voltages, the computing units generate a plurality of output currents; and based on the output currents, a multiply accumulate (MAC) of the input data and a plurality of conductance of the computing cells is generated.

### TECHNICAL FIELD

The disclosure relates in general to a memory device and a computing method thereof, and more particularly to an in-memory computing (IMC) memory device and an IMC method thereof.

### BACKGROUND

Along with enhancement of semiconductor technology, memory devices are used to execute in-memory computing (IMC). Phase changing memory (PCM) has been used to implement IMC. PMC is a new non-volatile memory having advantages of high density, low power consumption and so on.

Now, a novel PCMS (phase changing memory and selector) memory is developed based on Pall PCMS is a vertical memory cell integrating Ovonic Threshold Switch (OTS) and PCM. Stacking several PCMS is helpful in improving high memory density while maintaining PCM performance.

However, if PCM is used to execute multi-level IMC, a huge number of program-verify operations are needed and thus the operations are complicated.

In executing multi-level IMC operations, it is desirable to reduce complicated operations (for example, program-verify operations) under high storage density.

### SUMMARY

According to one embodiment, an in-memory computing (IMC) memory device is provided. The IMC memory device includes: a memory array including a plurality of computing units, each of the computing units including a plurality of parallel-coupling computing cells, the parallel-coupling computing cells of the same computing unit receiving a same input voltage; wherein a plurality of input data is converted into a plurality input voltages; after receiving the input voltages; the computing units generate a plurality of output currents; and based on the output currents, a multiply accumulate (MAC) of the input data and a plurality of conductance of the computing cells is generated.

According to another embodiment, an in-memory computing method is provided. The in-memory computing method includes: storing a plurality of conductance in a plurality of computing cells of a plurality of computing units of a memory array, each of the computing units including a plurality of parallel-coupling computing cells; converting a plurality of input data into a plurality input voltages; inputting the input voltages into the computing cells of the computing units, wherein the computing cells of the same computing unit receiving the same input voltage; after receiving the input voltages, generating a plurality of output currents from the computing units; and based on the output currents, generating a multiply accumulate (MAC) of the input data and the conductance of the computing cells.

### BRIEF DESCRIPTION OF THE DRAWINGS

FIG. 1 shows a multiply accumulate (MAC) operation of an in-memory computing (IMC) memory device.

FIG. 2 shows a multiply accumulate (MAC) operation of an in-memory computing (IMC) memory device according to one embodiment of the application.

FIG. 3 shows a voltage-current curve of the computing cell CC according to one embodiment of the application.

FIG. 4A shows the conductance of the computing unit CU according to one embodiment of the application,

FIG. 4B shows conductance and multi-level operations of the computing unit CU according to one embodiment of the application.

FIG. 5 shows an operation diagram of the IMC memory device according to one embodiment of the application.

FIG. 6 shows a structure of the computing cell CC according to one embodiment of the application.

FIG. 7 shows an IMC method according to one embodiment of the application.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DESCRIPTION OF THE EMBODIMENTS

Technical terms of the disclosure are based on general definition in the technical field of the disclosure. If the disclosure describes or explains one or some terms, definition of the terms is based on the description or explanation of the disclosure. Each of the disclosed embodiments has one or more technical features. In possible implementation, one skilled person in the art would selectively implement part or all technical features of any embodiment of the disclosure or selectively combine part or all technical features of the embodiments of the disclosure.

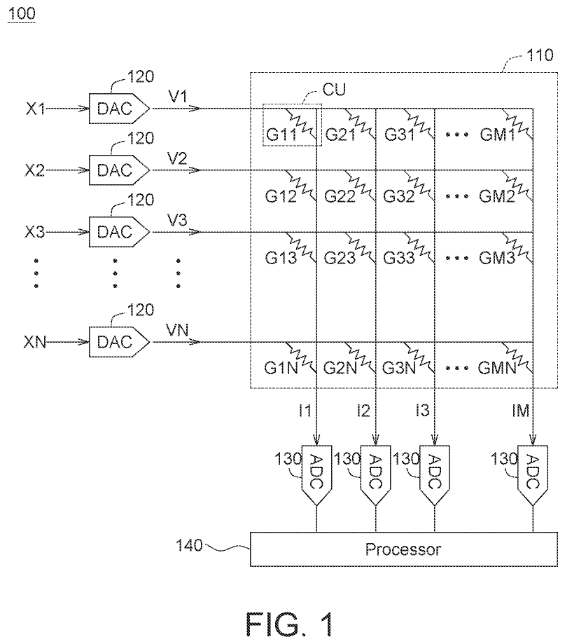

FIG. 1 shows a multiply accumulate (MAC) operation of an in-memory computing (IMC) memory device. As shown in FIG. 1, the memory device 100 at least includes a memory array 110, a plurality of first converters 120, a plurality of second converters 130 and a processor 140.

The memory array 110 includes a plurality of computing unit CU arranged in an array. The computing unit CU for example but not limited by includes a PCMS. Conductance of the computing units CU are G11˜GMN, respectively, wherein M and N are both positive integers. The first converters 120 are coupled to the memory array 110 for converting digital input data X1˜XN into analog input voltages (or said analog voltages) V1˜VN, respectively. The first converters 120 are for example but not limited by, digital analog converters (DAC).

After receiving the analog input voltages V1˜VN the computing units CU generate analog output currents I1˜IN. For example, the computing units CU on the first column receive the analog input voltages V1˜VN and generate the analog output current I1, wherein I1=V1*G11-FV2*G12+ . . . +VN*G1N. Generation of the analog output currents I2˜IN is the same or similar.

The second converters 130 are coupled to the memory array 110 for converting the analog output currents I1˜IN from the memory array 110 into the digital output data and feeding into the processor 140. The processor 140 generates MAC of the digital input data X1˜XN and the conductance G11˜GMN based on the digital output data from the second converters 130.

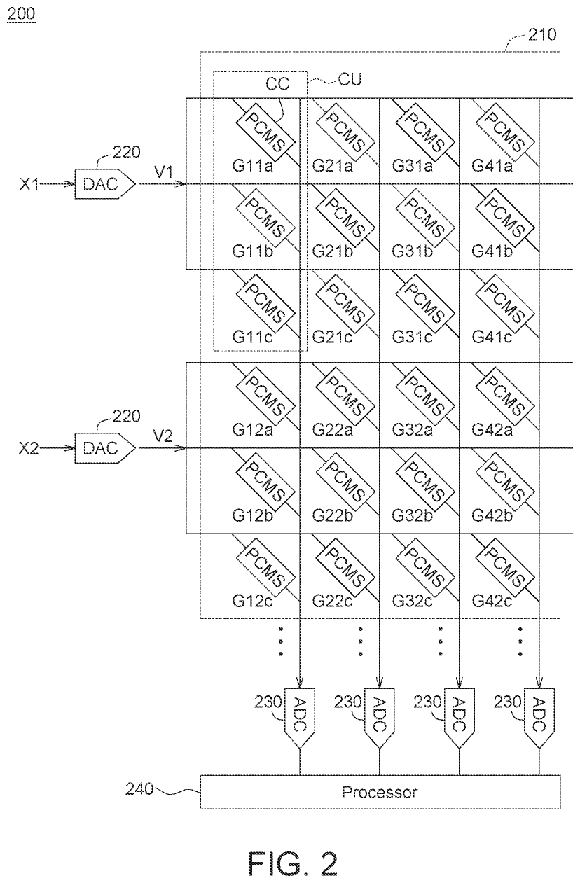

FIG. 2 shows a multiply accumulate (MAC) operation of an in-memory computing (IMC) memory device according to one embodiment of the application. As shown in FIG. 2, the memory device 200 at least includes a memory array 210, a plurality of first converters 220, a plurality of second converters 230 and a processor 240.

The memory array 210 includes a plurality of computing unit CU arranged in an array. Each of the computing units CU includes a plurality of parallel-coupled computing cells CC, the computing cells CC being for example but not limited by, PCMS. For example, in one computing unit CU, the conductance of the computing cells CC are G11a, G11b and G11c, respectively, then the equivalent conductance G11 of the computing unit CU is G11=G11a+G11b+G11c. The equivalent conductance of the computing units CU are G11˜GMN.

The first converters 220 are coupled to the memory array 210 for converting digital input data X1˜XN into analog input voltages (or said analog voltages) V1˜VN, respectively. The first converters 220 are for example but not limited by, digital analog converters (DAC).

After receiving the analog input voltages V1˜VN, the computing units CU generate analog output currents I1˜IN. For example, the computing units CU on the first column receive the analog input voltages V1˜VN and generate the analog output current I1, wherein:

I1=V1*G11a+V1*G11b+V1*G11c+V2*G12a+V2*G12b+V2*G12c+ . . . VN*G1Na+VN*G1Nb+VN*G1Nc=V1*(G11a+G11b+G11c)+V2*(G12a+G12P+G12c)+ . . . V N*(G1Na+G1Nb+G1Nc)=V1*G11+V2*G12+ . . . VN*G1N. Generation of the analog output currents I2˜IN is the same or similar.

The second converters 230 are coupled to the memory array 210 for converting the analog output currents I1˜IN from the memory array 210 into the digital output data and feeding into the processor 240. The processor 240 generates MAC of the digital input data X1˜XN and the conductance G11˜GMN based on the digital output data from the second converters 230.

In one embodiment of the application, by parallel-coupling several computing cells CC into one computing units CU, the memory device 200 is capable of executing multi-level MAC operations.

In one embodiment of the application, by programming the computing cell CC, the computing cell CC has a plurality of memory states. Here, the computing cell CC has two memory states, i.e., a reset state and a set state, but the application is not limited by this.

When the computing cell CC is programmed into the reset state, the computing cell CC has a first threshold voltage VtR; and when the computing cell CC is programmed into the set state, the computing cell CC has a second threshold voltage VtS, wherein the first threshold voltage VtR is higher than the second threshold voltage VtS. Also, the computing cell CC under the reset state has a first conductance Lc and the computing cell CC under the set state has a second conductance Hc wherein the first conductance Lc is lower than the second conductance Hc.

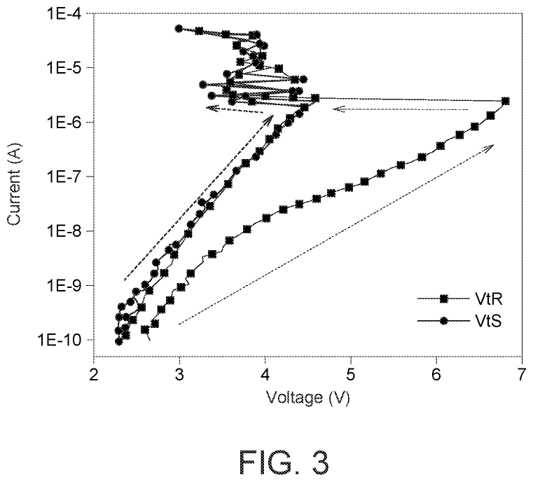

FIG. 3 shows a voltage-current curve of the computing cell CC according to one embodiment of the application. As shown in FIG. 3, in the case that the reading voltage is 4V, when the computing cell CC is in the reset state, the computing cell CC has a current about 2E−8(A)=2*10⁻⁸ (A) and thus the first conductance of the computing cell CC is about 2*10⁻⁸ A/4V=0.005 μS, and when the computing cell CC is in the set state, the computing cell CC has a current about 3E−7(A)=3*10⁻⁷ (A) and thus the second conductance of the computing cell CC is about 3*10⁻⁷A/4V=0.075 μS.

In one embodiment of the application, in performing MAC operations in the IMC memory device, by applying the reading voltage (for example but not limited by, as shown in FIG. 3, the reading voltage being 4V), the computing cells CC are operated in the subthreshold region to read the sub-threshold current. As shown in FIG. 3, when the reading voltage is 4V, the sub-threshold current difference between the set-state computing cell CC and the reset-state computing cell CC is large, which is helpful in raising determination accuracy.

In one embodiment of the application, in performing multi-level MAC operations in the IMC memory device, the input voltage may be Vread (the read voltage) or 0V, wherein Vread may be for example but not limited by 3-4,5V.

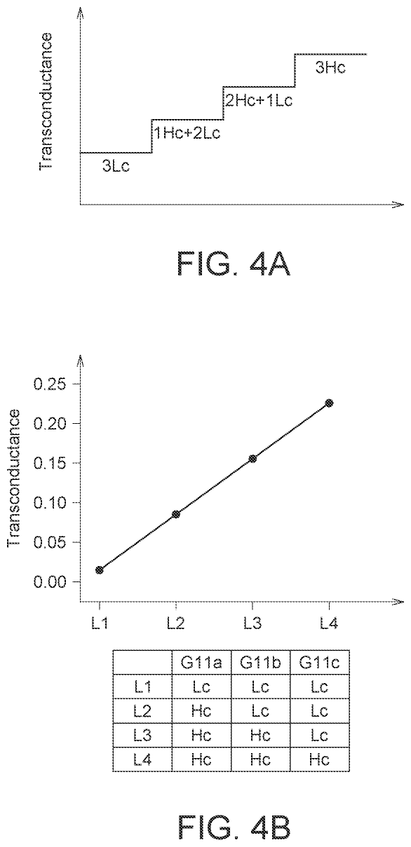

FIG. 4A shows the conductance of the computing unit CU according to one embodiment of the application. Here, the computing unit CU includes three parallel computing cells CC which is not to limit the application.

As shown in FIG. 4A, when the three computing cells CC are all in the reset state, the computing unit CU has the equivalent conductance of 3Lc; when one among the three computing cells CC is in the set state while the other two are in the reset state, the computing unit CU has the equivalent conductance of 1 Hc+2Lc; when two among the three computing cells CC are in the set state while the other one is in the reset state, the computing unit CU has the equivalent conductance of 2Hc+Lc; and when the three computing cells CC are all in the set state, the computing unit CU has the equivalent conductance of 3Hc.

In one embodiment of the application, in case that the computing unit CU includes three parallel computing cells CC, the computing unit CU supports four-level operations (or said, the memory device supports four-level operations, that is, the computing unit CU is a two-bit computing unit). In case that the computing unit CU includes seven parallel computing cells CC, the computing unit CU supports eight-level operations (or said, the memory device supports eight-level operations, that is, the computing unit CU is a three-bit computing unit), Thus, in case that the computing unit CU includes 2ⁿ-1 (n being a positive integer) parallel computing cells CC, the computing unit CU supports 2ⁿ-level operations (or said, the memory device supports 2ⁿ-level operations, that is, the computing unit CU is a n-bit computing unit).

FIG. 4B shows conductance and multi-level operations of the computing unit CU according to one embodiment of the application, Here, the computing unit CU includes three parallel computing cells CC which is not to limit the application. As shown in FIG. 4B, when the three computing cells CC are all in the reset state, the computing unit CU has the equivalent conductance of 3Lc, which is marked as L1. L2˜L4 have the similar meaning, That is, an equivalent conductance level of the computing unit CU is corresponding to a total conductance of the parallel computing cells.

Further, when all of the parallel-coupling computing cells are in the reset state, the equivalent conductance level of the computing unit is a lowest level (for example, L1); when a first part of the parallel-coupling computing cells are in the reset state and a second part of the parallel-coupling computing cells are in a set state, the equivalent conductance level of the computing unit is a middle level (for example, L2 and L3); and when all of the parallel-coupling computing cells are in the set state, the equivalent conductance level of the computing unit is a highest level (for example, L4). The lowest level is lower than the middle level, and the middle level is lower than the highest level.

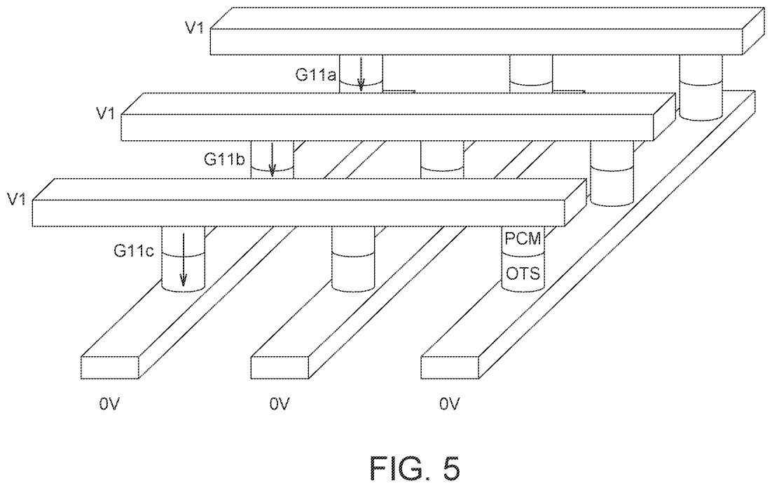

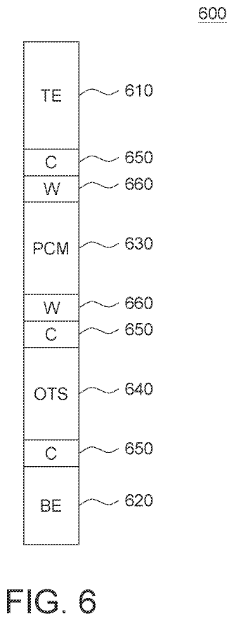

FIG. 5 shows an operation diagram of the MC memory device according to one embodiment of the application. In performing the multi-level MAC operations, as shown in FIG. 2 and FIG. 6, all the parallel-coupling computing cells CC of the same computing unit CU receive the same analog input voltage. Further, the bottom electrodes of the computing cells CC are applied by a reference voltage (for example but not limited by, 0V). By so, each of the computing cells CC outputs respective currents.

FIG. 6 shows a structure of the computing cell CC according to one embodiment of the application. As shown in FIG. 6, the computing cell CC (for example but not limited by, PCMS) 600 includes a top electrode (TE) 610, a bottom electrode 620, a PCM 630, an OTS 640, a plurality of barrier layers 650 and a plurality of adhesion layers 660.

In one embodiment of the application; the PCM 630 is for example but not limited by, (1) Ge1SbxTe1 (x being from 1 to 6) with doped SiOx or SiN; (2) Ge2Sb2Te5 with doped SiOx or SiN; (3) Ge2Sb2Te6 with doped SiOx or SiN; (4) Ge2Sb3Te5 with doped SiOx or SiN; (5) Ge2Sb4Te5 with doped SiOx or SiN; or (6) GexGaySbz with doped SiOx or SiN.

In one embodiment of the application, the OTS 640 is for example but not limited by, (1) Ge(x)Se(y)As(z) system; (2) Ge(x)Se(y)As(z) with Si doped; (3) Ge(x)Se(y)As(z) with In doped; or (4) Ge(x)Se(y)As(z) with carbon doped. Further, in other possible embodiments of the application, OTS 640 may be replaced by, for example but not limited to, threshold switch devices including MoS2, HfOx with Ag, and poly diode.

The barrier layers 650 are for example but not limited by, carbon carrier. The barrier layers 650 are at top and bottom of the PCM 630 and OTS 640. The adhesion layers 660 are for example but not limited by Tungsten (W) adhesion layers. The adhesion layers 660 are at top and bottom of the PCM 630 to improve adhesion.

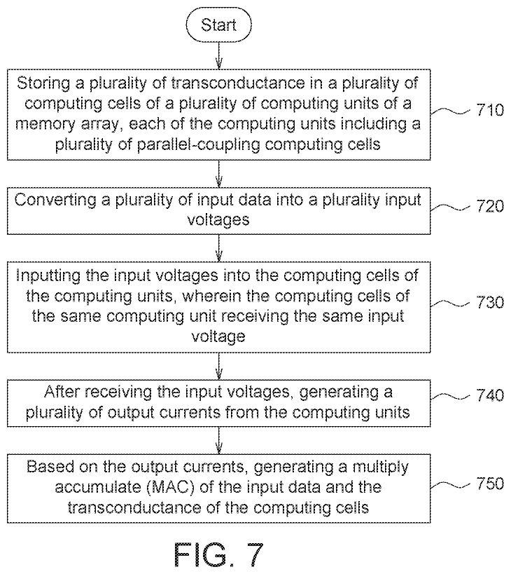

FIG. 7 shows an IMC method according to one embodiment of the application. The ICM method include: storing a plurality of conductance in a plurality of computing cells of a plurality of computing units of a memory array, each of the computing units including a plurality of parallel-coupling computing cells (710); converting a plurality of input data into a plurality input voltages (720); inputting the input voltages into the computing cells of the computing units, wherein the computing cells of the same computing unit receiving the same input voltage (730); after receiving the input voltages, generating a plurality of output currents from the computing units (740); and based on the output currents, generating a multiply accumulate (MAC) of the input data and the conductance of the computing cells (750).

The memory device of one embodiment of the application may be applicable in any emerging memories, for example but not limited by, Resistive Random Access Memory (RRAM), Magnetoresistive Random Access Memory (MRAM), Ferroelectric RAM (FeRAM) and so on.

In prior disclosure, if PCM are used to achieve multi-level AI (artificial intelligence) operations, a huge number of program-verify operations are needed to complicate the whole AI operations. But, in one embodiment of the application, by parallel-coupling a plurality of computing cells CC (for example but not limited by, PCMS) to form a computing unit CU, a huge number of program-verify operations are avoided and thus the whole AI operations are simplified. That is because, in one embodiment of the application, each of the computing units CU includes a plurality of parallel-coupling computing cells CC and each of the computing cells CC has at least two memory states (the reset state and the set state), by operating the computing cells CC in the sub-threshold region, the current discrimination between the read current at the reset state and the read current at the set state is enough high and thus the accuracy and discrimination of the multi-level AI operations are improved.

Further, in one embodiment of the application, the computing cells CC are arranged in cross points to achieve high storage density because the computing cell CC is small size. On the contrary, the current RRAM uses the transistors as the switching element, and thus it is difficult for the current RRAM to achieve high storage density.

It will be apparent to those skilled in the art that various modifications and variations can be made to the disclosed embodiments. It is intended that the specification and examples be considered as exemplary only, with a true scope of the disclosure being indicated by the following claims and their equivalents.

1. An in-memory computing (IMC) memory device including:
a memory array including a plurality of computing units, each of the computing units including a plurality of parallel-coupling computing cells, the parallel-coupling computing cells of the same computing unit receiving a same input voltage;
wherein
a plurality of input data is converted into a plurality input voltages;
after receiving the input voltages, the computing units generate a plurality of output currents; and
based on the output currents, a multiply accumulate (MAC) of the input data and a plurality of conductance of the computing cells is generated;
wherein the computing cell includes a top electrode, a bottom electrode, a phase changing memory (PCM), an ovonic threshold switch (OTS), a plurality of barrier layers and a plurality of adhesion layers;
wherein in performing multi-level MAC operations, all the computing cells of the computing unit receive the same one among the plurality input voltages; the bottom electrodes of the computing cells are applied by a reference voltage, and each of the computing cells outputs respective currents.

2. The IMC memory device according to claim 1, wherein
when the memory cell is programmed into a reset state, the computing cell has a first threshold voltage;
when the computing cell is programmed into a set state, the computing cell has a second threshold voltage;
the first threshold voltage is higher than the second threshold voltage; and
the computing cell under the reset state has a first conductance and the computing cell under the set state has a second conductance, wherein the first conductance is lower than the second conductance.

3. The IMC memory device according to claim 1, wherein the computing cell is a phase changing memory and selector (PCMS).

4. The IMC memory device according to claim 1, wherein in performing IMC MAC operations, the computing cells are operated in a subthreshold region to read a plurality of subthreshold currents as the output currents.

5. The IMC memory device according to claim 1, wherein when each of the computing units includes 2ⁿ-1 parallel-coupling computing cells, the IMC memory device supports 2ⁿ level operations, wherein n is a positive integer.

6. The IMC memory device according to claim 1, wherein an equivalent conductance level of the computing unit is corresponding to a total conductance of the parallel-coupling computing cells.

7. The IMC memory device according to claim 6, wherein
when all of the parallel-coupling computing cells are in a reset state, the equivalent conductance level of the computing unit is a lowest level;
when a first part of the parallel-coupling computing cells are in the reset state and a second part of the parallel-coupling computing cells are in a set state, the equivalent conductance level of the computing unit is a middle level; and
when all of the parallel-coupling computing cells are in the set state, the equivalent conductance level of the computing unit is a highest level;
wherein the lowest level is lower than the middle level, and the middle level is lower than the highest level.

8. The IMC memory device according to claim 1, wherein a read voltage applying to the computing cells is between 3-4.5V.

9. (canceled)

10. The IMC memory device according to claim 1, wherein
the barrier layers are at top and bottom of the PCM and OTS; and
the adhesion layers are at top and bottom of the PCM.

11. An in-memory computing method including:
storing a plurality of conductance in a plurality of computing cells of a plurality of computing units of a memory array, each of the computing units including a plurality of parallel-coupling computing cells;
converting a plurality of input data into a plurality input voltages;
inputting the input voltages into the computing cells of the computing units, wherein the computing cells of the same computing unit receiving the same input voltage;
after receiving the input voltages, generating a plurality of output currents from the computing units; and
based on the output currents, generating a multiply accumulate (MAC) of the input data and the conductance of the computing cells;
wherein the computing cell includes a top electrode, a bottom electrode, a phase changing memory (PCM), an ovonic threshold switch (OTS), a plurality of barrier layers and a plurality of adhesion layers;
wherein in performing multi-level MAC operations, all the computing cells of the computing unit receive the same one among the plurality input voltages; the bottom electrodes of the computing cells are applied by a reference voltage, and each of the computing cells outputs respective currents.

12. The IMC method according to claim 11, wherein
when the memory cell is programmed into a reset state, the computing cell has a first threshold voltage;
when the computing cell is programmed into a set state, the computing cell has a second threshold voltage;
the first threshold voltage is higher than the second threshold voltage; and
the computing cell under the reset state has a first conductance and the computing cell under the set state has a second conductance, wherein the first conductance is lower than the second conductance.

13. The IMC method according to claim 11, wherein the computing cell is a phase changing memory and selector (PCMS).

14. The IMC method according to claim 11, wherein in performing IMC MAC operations, the computing cells are operated in a subthreshold region to read a plurality of subthreshold currents as the output currents.

15. The IMC method according to claim 11, wherein when each of the computing units includes 2ⁿ-1 parallel-coupling computing cells, the IMC memory device supports 2ⁿ level operations, wherein n is a positive integer.

16. The IMC method according to claim 11, wherein an equivalent conductance level of the computing unit is corresponding to a total conductance of the parallel-coupling computing cells.

17. The IMC method according to claim 16, wherein
when all of the parallel-coupling computing cells are in a reset state, the equivalent conductance level of the computing unit is a lowest level;
when a first part of the parallel-coupling computing cells are in the reset state and a second part of the parallel-coupling computing cells are in a set state, the equivalent conductance level of the computing unit is a middle level; and
when all of the parallel-coupling computing cells are in the set state, the equivalent conductance level of the computing unit is a highest level;
wherein the lowest level is lower than the middle level, and the middle level is lower than the highest level.

18. The IMC method according to claim 11, wherein a read voltage applying to the computing cells is between 3-4.5V.

19. (canceled)

20. The IMC method according to claim 11, wherein
the barrier layers are at top and bottom of the PCM and OTS; and
the adhesion layers are at top and bottom of the PCM.
